(19) United States
(12) Patent Application Publication
(10) Pub. No.: US 2008/0230772 A1
(43) Pub. Date: Sep. 25, 2008

(54) DISPLAY DEVICE AND METHOD OF MANUFACTURING THE DISPLAY DEVICE

(76) Inventors: Norihiko KAMIURA, Kanazawa-shi (JP); Takumi SAWATANI, Ishikawa-gun (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 12/047,068

(22) Filed: Mar. 12, 2008

(30) Foreign Application Priority Data
Mar. 20, 2007 (JP) 2007-073618

(51) Int. Cl. H01L 51/50; H01L 51/56

(52) U.S. Cl. 257/40; 438/29; 257/E51.018

(57) ABSTRACT

A method of manufacturing a display device includes a step of forming an island-shaped first electrode, a step of forming a first insulation film, a step of forming a second insulation film, a step of removing the first insulation film, which is exposed from the second insulation film, in a self-alignment manner by using the second insulation film as a mask, a step of coating a liquid-phase material on the first electrode which is exposed from the first insulation film, and then drying the liquid-phase material, thus forming an organic active layer, and a step of forming a second electrode on the organic active layer. The first insulation film has higher lyophilic properties to the liquid-phase material for forming the organic active layer than the second insulation film.

### CROSS-REFERENCE TO RELATED APPLICATIONS

This application is based upon and claims the benefit of priority from prior Japanese Patent Application No. 2007-073618, filed Mar. 20, 2007, the entire contents of which are incorporated herein by reference.

### BACKGROUND OF THE INVENTION

1. Field of the Invention

The present invention relates generally to a display device and a method of manufacturing the display device, and more particularly to a display device including a self-luminous display element and a method of manufacturing this display device.

2. Description of the Related Art

In recent years, attention has been paid to an organic electroluminescence (EL) display device as a flat-panel display device. Since the organic EL display device includes self-luminous display elements, the organic display device has such features that the viewing angle is wide, no backlight is needed and thus reduction in thickness can be achieved, power consumption can be decreased, and high responsivity is obtained.

By virtue of these features, attention has been paid to the organic EL display device as a promising candidate for the next-generation flat-panel display device that is to replace the liquid crystal display devices. The organic EL display device includes an organic EL element in which an organic active layer having a light emission function is held between an anode and a cathode. The organic EL element has either one of a structure wherein a low molecular material is used for the organic active layer, and a structure wherein a high molecular material is used for the organic active layer.

In typical examples, the organic EL element using the low molecular material is formed by a dry process, and a multi-layer structure can easily be formed. On the other hand, in typical examples, the organic EL element using the high molecular material is formed by a selective coating method such as an ink jet method. The selective coating method has such an advantage that the efficiency of use of the material for forming the organic active layer is remarkably good.

In the case of forming the organic active layer with use of the high molecular material by the selective coating method, it is necessary to precisely coat the liquid-phase material on an effective part of each pixel (i.e. the surface of the anode that is exposed from partition walls). To meet this demand, use is made of a method in which pattern precision is improved by making use of differences in wettability between a material for forming a partition wall for isolating (insulating) neighboring pixels and a material for forming an anode, on the one hand, and a liquid-phase material for forming an organic active layer, on the other hand. In this case, the wettability of the partition wall material to the liquid-phase material for forming the organic active layer is designed to be low, and conversely the wettability of the anode material to the liquid-phase material is designed to be high.

In this case, the liquid-phase material, which is coated and lies on the partition wall, flows down from the partition wall toward the exposed effective part by a liquid-repellent function of the surface of the partition wall. However, since the liquid-phase material is not wettable on the partition wall, it is possible that the film thickness of the liquid-phase material may become extremely small at a peripheral portion of the effective part (i.e. in the vicinity of a part of contact between the partition wall and the anode). In such a case, the film thickness of the organic active layer, which is formed by drying the liquid-phase material, may also become extremely small at the peripheral portion.

At a thinned part of the organic active layer, short-circuit tends to easily occur between the electrode (cathode) that is disposed on the organic active layer and the anode, and a non-light-emission pixel (point defect) may occur. In addition, at the thinned part of the organic active layer, electric current may concentrate and the lifetime may decrease.

To solve the above problems, there is proposed a structure which includes a lyophilic insulation film having lyophilic properties for the partition wall, thereby to uniformly apply a coated liquid-phase material within the effective part (see, e.g. Jpn. Pat. Appln. KOKAI Publication No. 2002-202735).

When the lyophilic insulation film is to be formed, it is thinkable to form the lyophilic insulation film by the following method. An insulation film is formed, and a photoresist is formed on the insulation film. The photoresist is patterned by a photolithography process, and that portion of the insulation film, which is exposed from the patterned photoresist, is removed. Further, the photoresist is removed, and the lyophilic insulation film is formed. Since the photomask is used in these formation steps, it is necessary to make design in consideration of misalignment of the photomask.

Specifically, an aperture pattern of the lyophilic insulation film is made smaller than an aperture pattern of a liquid-repellent insulation film which is formed subsequently. Thereby, even if the aperture pattern of the lyophilic insulation film is misaligned with the aperture pattern of the liquid-repellent insulation film, the lyophilic insulation film is not covered with the liquid-repellent insulation film.

In the organic EL element, the part that contributes to light emission is a part where the organic active layer is held between a pair of electrodes. A part where the lyophilic insulation film is present does not contribute to light emission. Thus, if the aperture pattern of the lyophilic film is reduced in size, such a problem arises that the effective aperture ratio decreases.

### BRIEF SUMMARY OF THE INVENTION

The present invention has been made in consideration of the above-described problems, and the object of the invention is to provide a display device and a method of manufacturing the display device, wherein the aperture ratio does not decrease, a good display quality can be obtained and the lifetime can be increased.

According to a first aspect of the present invention, there is provided a method of manufacturing a display device, comprising: a step of forming an island-shaped first electrode in each of pixels on a substrate; a step of forming a first insulation film on the substrate on which the first electrode is formed; a step of forming a second insulation film, which has such a pattern as to isolate each pixel, on the first insulation film; a step of removing the first insulation film, which is exposed from the second insulation film, in a self-alignment manner by using the second insulation film as a mask; a step of coating a liquid-phase material on the first electrode which is exposed from the first insulation film, and then drying the liquid-phase material, thus forming an organic active layer; and a step of forming a second electrode on the organic active layer, wherein the first insulation film has higher lyophilic properties to the liquid-phase material for forming the organic active layer than the second insulation film.

According to a second aspect of the present invention, there is provided a display device comprising: a first electrode disposed in each of pixels; an organic active layer disposed on the first electrode; a second electrode disposed on the organic active layer; and a partition wall which is disposed in such a manner as to cover a peripheral edge of the first electrode, and isolates each pixel, wherein the partition wall is configured to include a first insulation film which has a first aperture portion and is formed of an inorganic material, and a second insulation film which is stacked on the first insulation film, has a second aperture portion, and is formed of an organic material, and an edge of the first aperture portion of the first insulation film is substantially flush with an edge of the second aperture portion of the second insulation film.

The present invention can provide a display device and a method of manufacturing the display device, wherein the aperture ratio does not decrease, a good display quality can be obtained and the lifetime can be increased.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate presently preferred embodiments of the invention, and together with the general description given above and the detailed description of the preferred embodiments given below, serve to explain the principles of the invention.

FIG. 1 schematically shows the structure of an organic EL display device according to an embodiment of the present invention;

FIG. 2 is a cross-sectional view that schematically shows a cross-sectional structure of the organic EL display device shown in FIG. 1;

FIG. 3 is a cross-sectional view that schematically shows an example of a more concrete structure of a partition wall shown in FIG. 2;

FIG. 4 is a cross-sectional view that schematically shows another example of a more concrete structure of the partition wall shown in FIG. 2;

FIG. 5 is a cross-sectional view that schematically shows still another example of a more concrete structure of the partition wall shown in FIG. 2;

FIG. 6A is a view for describing a fabrication step for forming an organic EL element, illustrating a step of forming a first electrode;

FIG. 6B is a view for describing a fabrication step for forming the organic EL element, illustrating a step of forming a first insulation film;

FIG. 6C is a view for describing a fabrication step for forming the organic EL element, illustrating a step of forming a second insulation film;

FIG. 6D is a view for describing a fabrication step for forming the organic EL element, illustrating a step of removing the first insulation film in a self-alignment manner by using the second insulation film as a mask;

FIG. 6E is a view for describing a fabrication step for forming the organic EL element, illustrating a step of forming an organic active layer; and

FIG. 6F is a view for describing a fabrication step for forming the organic EL element, illustrating a step of forming a second electrode.

### DETAILED DESCRIPTION OF THE INVENTION

A display device according to an embodiment of the present invention will now be described with reference to the accompanying drawings. In this embodiment, a self-luminous display device, such as an organic EL (electroluminescence) display device, is described as an example of the display device.

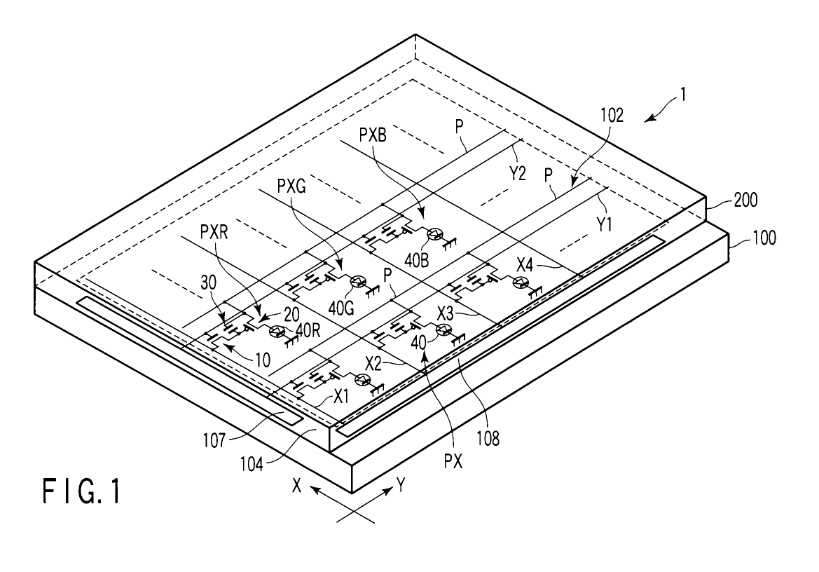

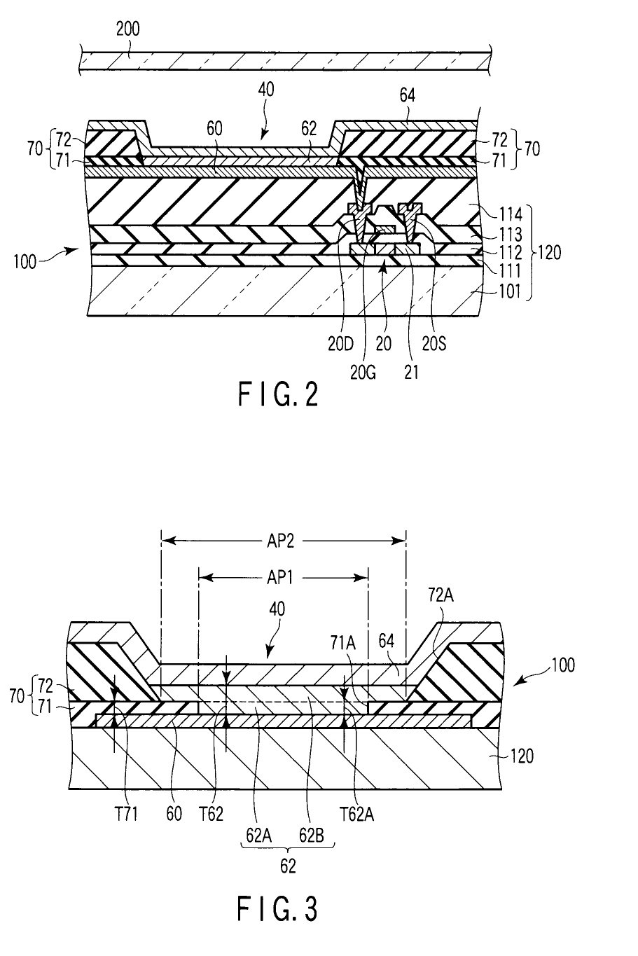

As is shown in FIG. 1 and FIG. 2, an organic EL display device 1 includes an array substrate 100 with a display area 102 for displaying an image. The display area 102 is composed of a plurality of pixels PX (R, G, B) that are arranged in a matrix. At least the display area 102 of the array substrate 100 is sealed by a sealing member 200.

The array substrate 100 includes a plurality of scanning lines Ym (m=1, 2, . . . ) which are disposed along a row direction of pixels PX (i.e. Y direction in FIG. 1), a plurality of signal lines Xn (n=1, 2, . . . ) which are disposed along a column direction (X direction in FIG. 1) that is substantially perpendicular to the scanning lines Ym, and a power supply line P for supplying power to organic EL elements 40.

The array substrate 100 further includes, in its peripheral area 104 that is provided around the outer periphery of the display area 102, at least a part of a scanning line driving circuit 107 which supplies scanning signals to the scanning lines Ym, and at least a part of a signal line driving circuit 108 which supplies video signals to the signal lines Xn. All scanning lines Ym are connected to the scanning line driving circuit 107. All signal lines Xn are connected to the signal line driving circuit 108.

Each pixel PX (R, G, B) comprises a pixel circuit and a display element which is driven and controlled by the pixel circuit. The pixel circuit shown in FIG. 1 is merely an example, and, needless to say, pixel circuits of other structures are applicable. In the example shown in FIG. 1, the pixel circuit includes a pixel switch 10 having a function of electrically separating an ON pixel and an OFF pixel and holding a video signal to the ON pixel; a driving transistor 20 that supplies a desired driving current to the display element on the basis of the video signal that is supplied via the pixel switch 10; and a storage capacitance element 30 that holds a gate-source potential of the driving transistor 20 for a predetermined time period. The pixel switch 10 and driving transistor 20 are composed of, e.g. thin-film transistors. In this example, thin-film transistors having semiconductor layers of polysilicon are applied.

A gate 20G of the driving transistor 20 is connected to the drain of the pixel switch 10 and to one end of the storage capacitance element 30. A source 20S of the driving transistor 20 is connected to the power supply line P and the other end of the storage capacitance element 30.

The display element is composed of an organic EL element 40 (R, G, B) which is a self-luminous element. Specifically, a red pixel PXR includes an organic EL element 40R that principally emits light of a red wavelength. A green pixel PXG includes an organic EL element 40G that principally emits light of a green wavelength. A blue pixel PXB includes an organic EL element 40B that principally emits light of a blue wavelength.

The organic EL elements 40 (R, G, B) of the respective colors have basically the same structure. For example, as shown in FIG. 2, the organic EL element 40 is disposed on a wiring substrate 120. The wiring substrate 120 includes insulation layers, such as an undercoat layer 111, a gate insulation film 112, an interlayer insulation film 113 and an organic insulation film 114, which are provided on an insulative support substrate 101 such as a glass substrate or a plastic sheet. The wiring substrate 120 further includes the pixel switch 10, driving transistor 20, storage capacitance element 30, scanning line driving circuit 107, signal line driving circuit 108, and various wring lines (scanning lines, signal lines, power supply line, etc.).

The organic EL element 40 comprises a first electrode 60 that is formed in an insular shape in each pixel PX, a second electrode 64 that is disposed to be opposed to the first electrode 60, and an organic active layer 62 that is held between the first electrode 60 and the second electrode 64.

The first electrode 60 is disposed on the organic insulation film 114 on the surface of the wiring substrate 120 and functions as, for example, an anode. The first electrode 60 is electrically connected to the drain 20D of the driving transistor 20 via a contact-hole that is formed in the organic insulation film 114.

The organic active layer 62 is disposed on the first electrode 60 and includes at least a light-emitting layer. The organic active layer 62 may include layers other than the light-emitting layer. For example, the organic active layer 62 may include a hole transporting layer, a hole injection layer, a blocking layer, an electron transporting layer, an electron injection layer, and a buffer layer, or the organic active layer 62 may include a layer in which the functions of these layers are integrated. The light-emitting layer is formed of an organic compound having a light emission function of emitting red, green or blue light. At least a part of the organic active layer 62 is formed of a high polymer material, and the organic active layer 62 can be formed by coating a liquid-phase material by a selective coating method such as an ink jet method, and then drying the liquid-phase material. The hole transportation layer has a thickness of, e.g. about 200 Å. The light-emitting layer has a thickness of, e.g. about 1000 to 3000 Å.

The second electrode 64 is disposed on the organic active layer 62, and functions as, for example, a cathode. The second electrode 64 is disposed over the entire display area 102, and is connected to a second electrode power supply line of a common potential, namely a ground potential in this example, which is disposed on a periphery of the display area 102.

The array substrate 100 includes partition walls 70 that separate the pixels RX (R, G, B) in the display area 102. The partition walls 70 are arranged in a lattice shape so as to cover the entire the peripheral edges of the first electrodes 60. The partition wall 70 are configured to include a first insulation film 71 and a second insulation film 72 which is stacked on the first insulation film 71.

The first insulation film 71 is formed of a material which has lyophilic properties to the high polymer liquid-phase material for forming the organic active layer 62. The first insulation film 71 is formed of an inorganic material such as silicon oxide (SiO₂) or silicon nitride (SiN). The second insulation film 72 is formed of a material which has liquid-repellent properties to the high polymer liquid-phase material for forming the organic active layer 62, or at least the surface of the second insulation film 72 is treated to have liquid-repellent properties. The second insulation film 72 is formed of, e.g. an organic material such as an acrylic resin. In short, the first insulation film 71 has higher lyophilic properties to the liquid-phase material for forming the organic active layer 62 than the second insulation film 72.

Next, examples of the structure of the partition walls according to the present embodiment are described in greater detail.

As is shown in FIG. 3, in each pixel PX, a first insulation film 71 has an edge 71A which defines a first aperture portion AP1. Specifically, the first insulation film 71 is disposed so as to cover a peripheral edge portion of a first electrode 60 which is formed in an independent island shape on the wiring substrate 120, and the first insulation film 71 electrically isolates the first electrode 60 in each pixel. In addition, the first aperture portion AP1, which is surrounded by the edge 71A of the first insulation film 71, exposes the first electrode 60 and makes it possible to dispose an organic active layer 62 on the first electrode 60.

In each pixel PX, a second insulation film 72 has an edge 72A which defines a second aperture portion AP2. Specifically, the second insulation film 72 is stacked on the first insulation film 71. Like the first aperture portion AP1, the second aperture portion AP2, which is surrounded by the edge 72A of the second insulation film 72, exposes the first electrode 60 and makes it possible to dispose the organic active layer 62 on the first electrode 60.

The first aperture portion AP1 of the first insulation film 71 has a pattern which is patterned in a self-alignment manner with the use of the second insulation film 72 as a mask. Specifically, the first aperture portion AP1 and the second aperture portion AP2 have substantially similar shapes and their centers substantially agree. In other words, the distance between the edge 71A of the first aperture portion AP1 and the edge 72A of the second aperture portion AP2 is substantially equal and isotropic in every direction within the plane of the substrate.

In the example shown in FIG. 3, the first aperture portion AP1 is set at a size smaller than the second aperture portion AP1. Accordingly, the edge 72A of the second insulation film 72 is retreated from the edge 71A of the first insulation film 71. In other words, the first insulation film 71 is exposed from the edge 72A of the second insulation film 72 with a substantially equal width. Thereby, a stepped portion is formed by the first insulation film 71 and the second insulation film 72, and at least the exposed part of the first insulation film 71 is in contact with the organic active layer 62. The width of exposure of the first insulation film 71 from the second insulation film 72 (i.e. the distance from the edge 71A to the edge 72A) should preferably be set at about 5 μm at most.

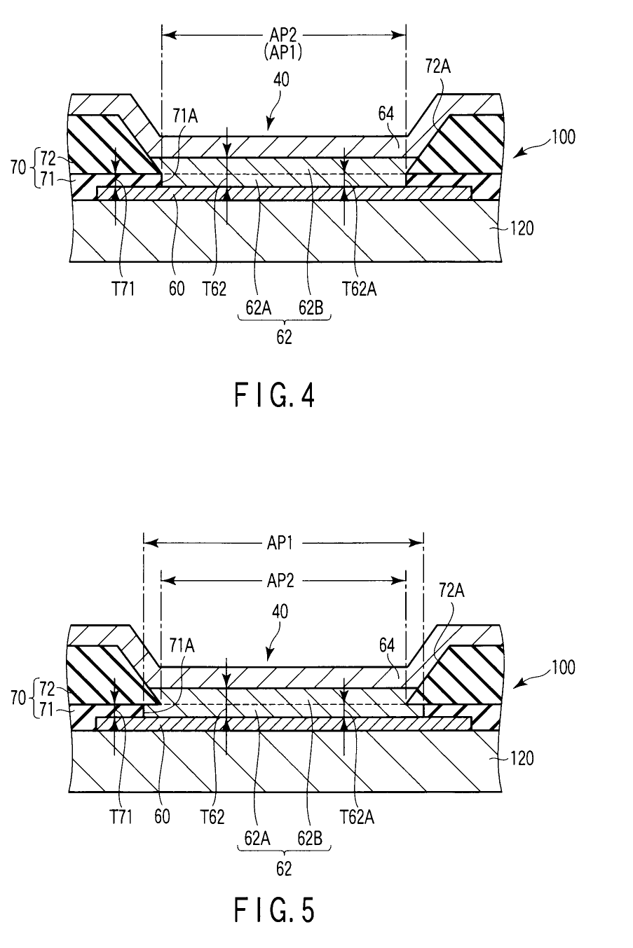

In an example shown in FIG. 4, the size of the first aperture portion AP1 and the size of the second aperture portion AP2 are set to be equal. Thus, the edge 71A of the first aperture portion AP1 of the first insulation film 71 substantially agrees with the edge 72A of the second aperture portion AP2 of the second insulation film 72. In other words, the edge 71A and the edge 72A are flush with each other. Thereby, at least the edge 71A of the first insulation film 71 is in contact with the organic active layer 62.

In an example shown in FIG. 5, the size of the first aperture portion AP1 is set to be greater than the size of the second aperture portion AP2. Accordingly, the edge 71A of the first aperture portion AP1 of the first insulation film 71 is retreated from the edge 72A of the second aperture portion AP2 of the second insulation film 72. Specifically, the second insulation film 72 is disposed so as to overlap the edge 71A of the first insulation film 71 and to expose the edge 71A of the first insulation film 71. In other words, the second insulation film 72 is disposed so as to project from the edge 71A toward the inside of the pixel, thus forming an overhang. In this case, the second insulation film 72 projects from the edge 71A of the first insulation film 71 with a substantially equal width. Thereby, at least the edge 71A of the first insulation film 71 is in contact with the organic active layer 62. The overhang width of the second insulation film 72 from the first insulation film 71 (i.e. the distance from the edge 71A to the edge 72A) should preferably be set at about 5 μm at most.

According to the organic EL display device 1 including the partition walls 70 with the above-described structure, in the case of forming the organic active layer 62 including at least one organic layer which is formed by a selective coating method with use of a high polymer liquid-phase material, when the liquid-phase material is coated and applied toward the first electrode 60, the liquid-phase material, which lies on the partition walls 70 or reaches a substantially central part of the first electrode 60, spreads so as to be attracted to the lyophilic first insulation film 71 that is disposed on the peripheral part, and is put in contact with at least the edge 71A of the first insulation film 71. In other words, the liquid-phase material has low wettability with the second insulation film 72, but has high wettability with the first insulation film 71 which corresponds to the bottom portions of the partition walls 70. Thus, it is possible to prevent the thickness of the organic active layer 62, which is formed after the liquid-phase material is dried, from decreasing at the peripheral part (in the vicinity of the partition walls). Thereby, the thickness of the organic active layer 62 within at least the first aperture portion AP1 can be made substantially uniform.

Therefore, short-circuit between the first electrode 60 and the second electrode 64 can be prevented, and the manufacturing yield can be improved. Moreover, it is possible to suppress a decrease in lifetime due to concentration of electric current at a thinned part of the organic active layer 62.

Besides, the first insulation film 71 is formed by patterning in a self-alignment manner with use of the second insulation film 72 as a mask. Thereby, a photomask for patterning the first insulation film 71 is needless, and the manufacturing cost can be reduced. In a patterning process that requires a photomask, there is a concern that the photomask or a member supporting the photomask, for instance, may come in contact with and damage an already formed array pattern such as partition walls. In the present embodiment, however, since the patterning is performed by using the second insulation film 72 as a mask, damage to the array pattern can be suppressed.

Furthermore, the effective aperture ratio, which contributes to light emission, can freely be set. Specifically, by setting the etching condition of the first insulation film 71 at an under-level, the first insulation film 71 can be exposed from the second insulation film 72, as shown in FIG. 3. In addition, by setting the etching condition of the first insulation film 71 at an over-level, an overhang can be formed by the second insulation film 72, as shown in FIG. 5.

Therefore, it is possible to provide a display device and a method of manufacturing the display device, wherein the aperture ratio does not decrease, a good display quality can be obtained and the lifetime can be increased.

As regards the thickness of the above-described first insulation film 71, consideration may be given to a thickness T71 of that portion of the first insulation film 71, which overlaps the peripheral edge of the first electrode 60. In the structure in which the organic active layer 62 includes the first organic layer 62A having a hole transporting function and the second organic layer 62B having a light emission function, it is preferable that the thickness T71 of the first insulation film 71 overlapping the first electrode 60 be set, at least, to be equal to or greater than a thickness T62A of the first organic layer 62A. The thickness T71 is set at, e.g. 200 Å or more.

Thereby, the first organic layer 62A, which is first formed, can surely be put in contact with the edge 71A of the first insulation film 71, and a decrease in thickness of the first organic layer 62A in the vicinity of the partition walls 70 (i.e. in the vicinity of the first insulation film 71) can be suppressed. Therefore, even if the thickness of the organic layer 62B, which is subsequently formed, decreases in the vicinity of the partition walls 70, short-circuit between the first electrode 60 and the second electrode 64 can be prevented.

On the other hand, it is preferable that the thickness T71 of the first insulation film 71 overlapping the first electrode 60 be set to be equal to or less than a total thickness T62 of the organic active layer 62, and the thickness T71 is set at, e.g. 8000 Å or less, and preferably 4000 Å or less.

Next, a method of manufacturing the organic EL display device is described. In the description below, it is assumed that the partition walls 70 are formed so as to have a structure as shown in FIG. 4, and that the organic active layer 62 is formed by a selective coating method with use of a high polymer material.

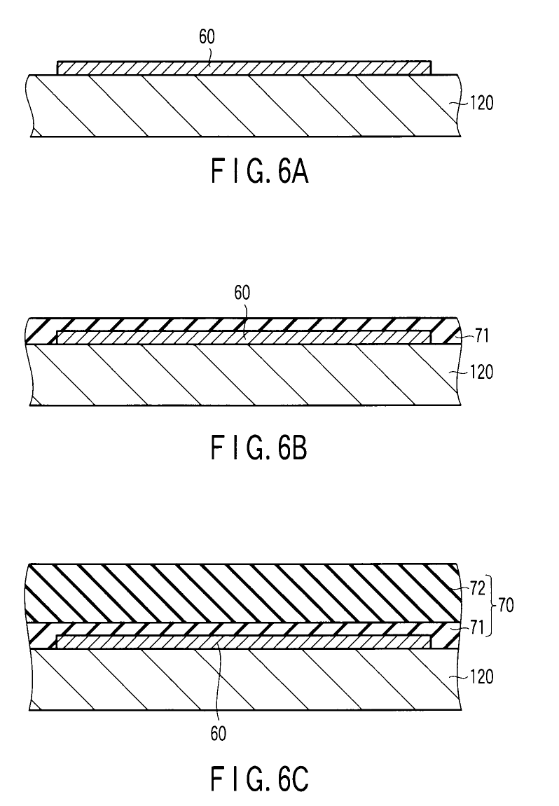

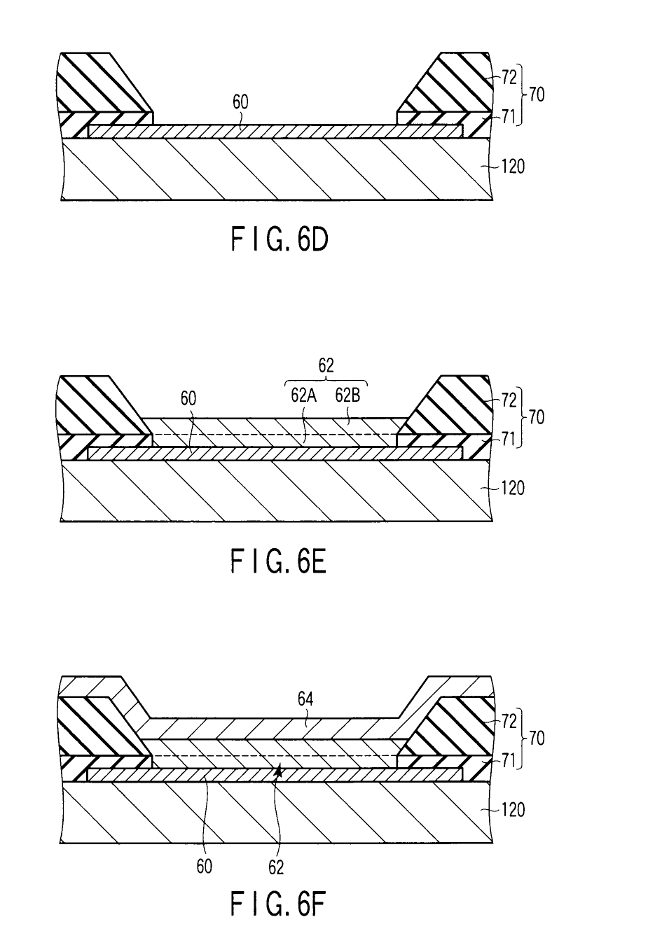

To start with, as shown in FIG. 6A, an island-shaped first electrode 60 is formed in each pixel on the wiring substrate 120. Specifically, processes, such as formation of a metal film and an insulation film and patterning, are repeated, and the wiring substrate 120 is prepared. In the wiring substrate 120, a pixel switch 10, a driving transistor 20, a storage capacitance element 30, a scanning line driving circuit 107, a signal line driving circuit 108, a signal line Xn, a scanning line Ym, a power supply line P, etc., are formed on a support substrate 101. A first electrode 60, which is in contact with a drain 20D of a driving transistor 20, is formed on the wiring substrate 120. The first electrode 60 may, in general, be formed by a photolithography process, or may be formed by a mask sputter method.

Subsequently, as shown in FIG. 6B, a first insulation film 71 is formed on the wiring substrate 120 on which the first electrode 60 is formed. In this step, a silicon oxide (SiO₂) film with a film thickness of 500 Å is formed over the entire surface of the wiring substrate 120 by, e.g. CVD.

Then, as shown in FIG. 6C, a second insulation film 72, which has such a pattern as to isolate each pixel, is formed on the first insulation film 71. Specifically, a photosensitive resin material, such as an acrylic resin material, is formed on the first insulation film 71. The photosensitive resin material is patterned by, e.g. a photolithography process and is then baked. Thereby, a lattice-shaped second insulation film 72, which forms a second aperture portion AP2 that surrounds each pixel, is formed.

Following the above, as shown in FIG. 6D, using the second insulation film 72 as a mask, the first insulation film 71, which is exposed from the second insulation film 72, is removed in a self-alignment manner. Specifically, using the second insulation film 72 as a mask pattern, the first insulation film 71 covering the first electrode 60 is dry-etched. By this etching process, a first aperture portion AP1, from which the first electrode 60 is exposed, is formed, and the first insulation film 71 is left under the second insulation film 72. Thus, partition walls 70 overlapping peripheral edges of the first electrode 60 are formed.

Subsequently, as shown in FIG. 6E, an organic active layer 62 is formed on the first electrode 60, which is exposed from the first insulation film 71. In this embodiment, the organic active layer 62 has a two-layer structure. To begin with, a first liquid-phase material, which is formed of a high-polymer organic material with a hole transporting function, is successively sprayed by a selective coating method on the pixels which are partitioned by the partition walls 70, and is coated on the first electrode 60. The first liquid-phase material, which is thus coated, is attracted by the lyophilic first insulation film 71 that is exposed at the lower part of the partition wall 70 that is disposed at the peripheral part of each pixel. Thus, the first liquid-phase material is uniformly spread within each pixel, without the spreading of the first liquid-phase material being hindered. Thereafter, a drying process is performed, for example, at 200° C. for five minutes, and solvent included in the first liquid-phase material is removed. Thereby, a first organic layer 62A having a thickness of 200 Å is formed. Subsequently, a second liquid-phase material, which is formed of a high-polymer organic material with a light-emitting function, is successively sprayed by a similar selective coating method on the pixels which are partitioned by the partition walls 70, and is coated on the first organic layer 62A. The second liquid-phase material, which is thus coated, is also uniformly spread within the pixel. Thereafter, a drying process is performed, for example, at 150° C. for 60 minutes, and solvent included in the second liquid-phase material is removed. Thereby, a second organic layer 62B having a thickness of 2000 Å is formed on the first organic layer 62A. In this manner, the organic active layer 62, in which the first organic layer 62A and second organic layer 62B are stacked, is formed.

Subsequently, as shown in FIG. 6F, a second electrode 64, which is common to a plurality of pixels, is formed on the organic active layer 62. Specifically, an electrically conductive layer, which becomes the second electrode, is formed by a vacuum evaporation method. Then, sealing is effected by a sealing member 200 in an atmosphere of an inert gas, for example, nitrogen (N₂) gas or argon (Ar) gas.

According to the thus fabricated organic EL display device, it was confirmed that light is uniformly emitted in a region corresponding to the effective part of each pixel. Therefore, electric current does not concentrate at a part of the organic active layer, and with the adoption of this structure, the lifetime of the organic EL element can be increased, and the display quality can be enhanced.

The present invention is not limited directly to the above-described embodiments. In practice, the structural elements can be modified without departing from the spirit of the invention. Various inventions can be made by properly combining the structural elements disclosed in the embodiments. For example, some structural elements may be omitted from all the structural elements disclosed in the embodiments. Furthermore, structural elements in different embodiments may properly be combined.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method of manufacturing a display device, comprising:
a step of forming an island-shaped first electrode in each of pixels on a substrate;
a step of forming a first insulation film on the substrate on which the first electrode is formed;
a step of forming a second insulation film, which has such a pattern as to isolate each pixel, on the first insulation film;
a step of removing the first insulation film, which is exposed from the second insulation film, in a self-alignment manner by using the second insulation film as a mask;
a step of coating a liquid-phase material on the first electrode which is exposed from the first insulation film, and then drying the liquid-phase material, thus forming an organic active layer; and
a step of forming a second electrode on the organic active layer,
wherein the first insulation film has higher lyophilic properties to the liquid-phase material for forming the organic active layer than the second insulation film.

2. A display device comprising:
a first electrode disposed in each of pixels;
an organic active layer disposed on the first electrode;
a second electrode disposed on the organic active layer; and
a partition wall which is disposed in such a manner as to cover a peripheral edge of the first electrode, and isolates each pixel,
wherein the partition wall is configured to include a first insulation film which has a first aperture portion and is formed of an inorganic material, and a second insulation film which is stacked on the first insulation film, has a second aperture portion, and is formed of an organic material, and
an edge of the first aperture portion of the first insulation film is substantially flush with an edge of the second aperture portion of the second insulation film.

3. The display device according to claim 2, wherein the organic active layer includes a first organic layer having a hole-transporting function, and a second organic layer having a light-emitting function, and
a thickness of the first insulation film overlapping a peripheral edge of the first electrode is at least equal to or greater than a thickness of the first organic layer.

4. The display device according to claim 2, wherein a thickness of the first insulation film overlapping a peripheral edge of the first electrode is equal to or less than a total thickness of the organic active layer.

5. The display device according to claim 2, wherein the first insulation film is formed of silicon oxide or silicon nitride.

6. The display device according to claim 2, wherein at least a surface of the second insulation film has liquid-repellent properties.
